(19) United States
(12) Patent Application Publication
(10) Pub. No.: US 2015/0077932 A1
(43) Pub. Date: Mar. 19, 2015

(54) SHIELDING ASSEMBLY AND ELECTRONIC DEVICE

(71) Applicants: HON HAI PRECISION INDUSTRY CO., LTD., New Taipei (TW); HONG FU JIN PRECISION INDUSTRY (ShenZhen) CO., LTD, Shenzhen (CN)

(72) Inventor: QIANG CHAI, Shenzhen (CN)

(73) Assignees: HON HAI PRECISION INDUSTRY CO., LTD., New Taipei (TW); HONG FU JIN PRECISION INDUSTRY (ShenZhen) CO., LTD, Shenzhen (CN)

(21) Appl. No.: 14/150,746

(22) Filed: Jan. 8, 2014

(30) Foreign Application Priority Data
Sep. 13, 2013 (CN) 2013104165371

(51) Int. Cl. H05K 9/00; G06F 1/20

(52) U.S. Cl. CPC H05K 9/0024; G06F 1/20
USPC 361/679.54; 174/377

(57) ABSTRACT

A shielding assembly is used to shield electronic element positioned on a motherboard of an electronic device. The shielding assembly includes a shielding frame fixed to a first surface of the motherboard, a heat dissipating module, and a shielding plate. The heat dissipating module is detachably assembled to the shielding frame. When the heat dissipating module is assembled to the shielding frame, the heat dissipating module and the shielding frame form a shielding space to receive the electronic element. The shielding plate is fixed to a second surface of the motherboard opposite to the shielding frame to completely shield the electronic element.

### BACKGROUND

1. Technical Field

The disclosure generally relates to shielding assemblies, and particularly to shielding assemblies used in electronic devices.

2. Description of Related Art

Electromagnetic interference (EMI) occurs between neighboring electronic components or circuits due to inductive couplings. To avoid the occurrence of EMI, shielding structures are commonly employed to absorb as much EMI radiation energy as possible for the electronic components or the circuits. Take central processor units (CPU) as an example; to reduce the EMI of the CPU, one way is to embed the CPU into a motherboard and partially shield the CPU with the motherboard. However, in this situation, when CPU frequency is increased, the EMI of the CPU becomes strong and may still interfere other electronic components. Alternatively, an extra shield may be employed to completely cover most portions of the motherboard. However, the extra shield may increase a volume of the electronic device.

Therefore, there is room for improvement within the art.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the disclosure.

FIG. 1 is an exploded view of an electronic device including a shielding assembly, according to an exemplary embodiment of the disclosure.

FIG. 2 is a partially assembled view of the electronic device shown in FIG. 1.

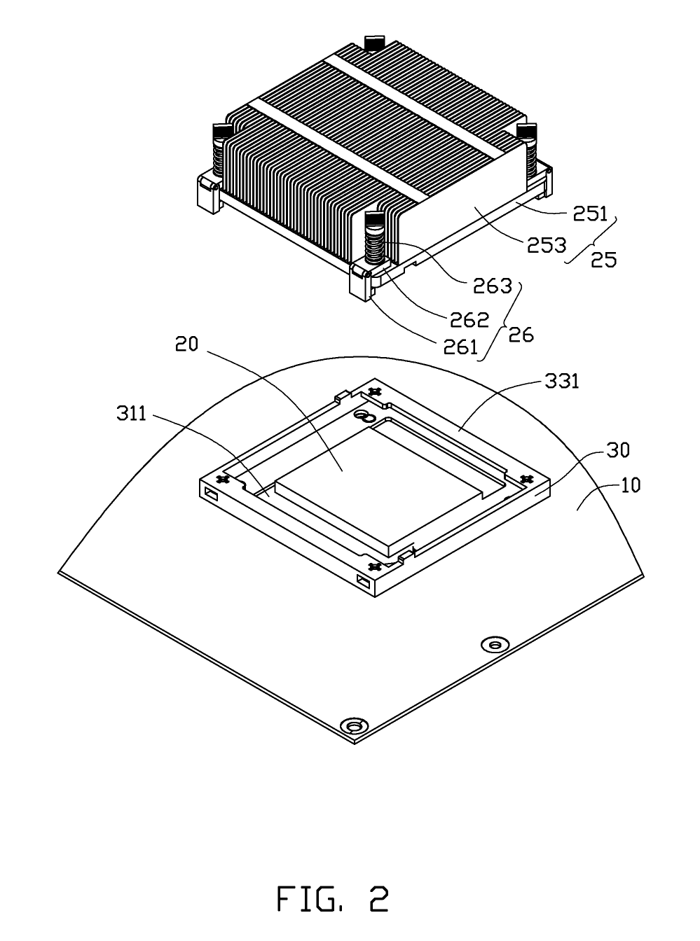

FIG. 3 is an assembled view of the electronic device shown in FIG. 1.

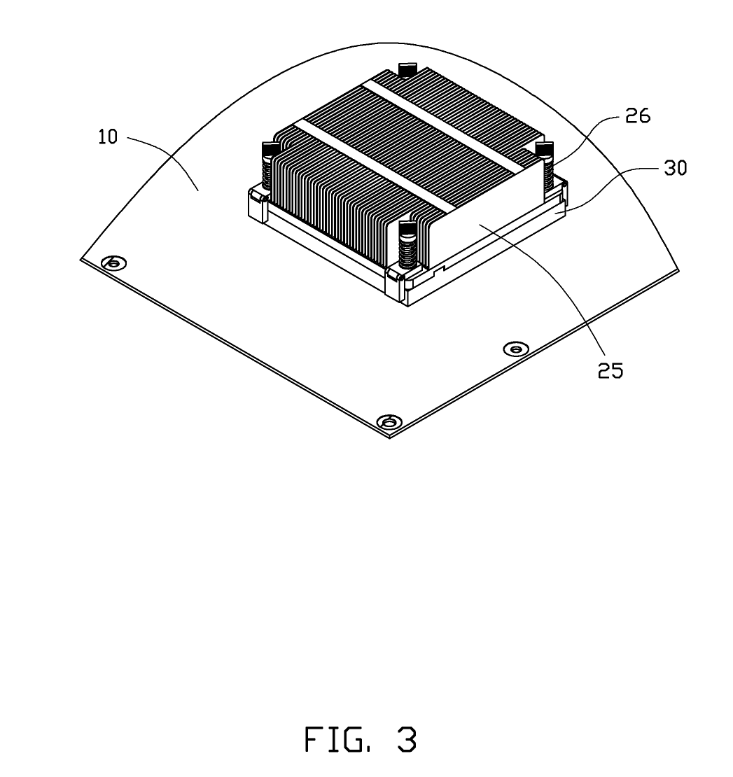

### DETAILED DESCRIPTION

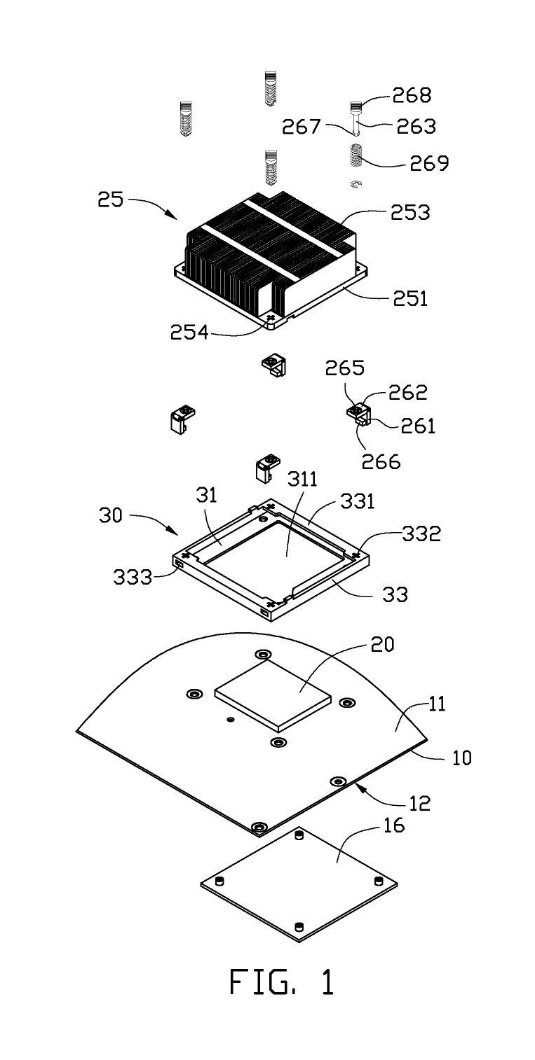

FIG. 1 is a schematic view of an electronic device including a shielding assembly, according to an exemplary embodiment of the disclosure. The electronic device further includes a motherboard 10 and a central processor unit (CPU) 20 positioned on the motherboard 10. The motherboard 10 includes a first surface 11 and a second surface 12 opposite to the first surface 11. The first surface 11 and the second surface 12 are coated with an insulating layer which may be formed by epoxy resin. The CPU 20 is positioned on the first surface 11.

The shielding assembly includes a shielding plate 16, a heat dissipating module 25, and a shielding frame 30. The shielding plate 16 is secured to the second surface 12 opposite to the CPU 20 so that the CPU 20 is completely shielded. The shielding frame 30 is positioned on the first surface 11 and surrounds the CPU 20. The heat dissipating module 25 covers on the shielding frame 30 to form a shielding space. The CPU 20 is received in the shielding space. In other embodiment, the CPU 20 may be other electronic element of the electronic device which needs to be shielded.

The heat dissipating module 25 includes a metallic base 251, a plurality of heat sinks 253 positioned on a surface of the base 251, and a plurality of fastening assemblies 26 configured to fasten the base 251 to the shielding frame 30. A first latching hole 254 is defined at each corner of the base 251. In this embodiment, there are one fastening assembly 26 corresponding to each first latching holes 254. Each fastening assembly 26 includes a fixing plate 261, a latching plate 262 hinged to the fixing plate 261, a latching bolt 263 and an elastic member 269. A latching block 266 protrudes from an end of the fixing plate 261 facing the latching plate 262. A through hole 265 is defined in the latching plate 262. In this embodiment, the through hole 265 is substantially cross-shaped. The latching plate 262 is fixed to the base 251 by the latching bolt 263 via the through hole 265. The latching block 266 is latched to the shielding frame 33. The latching bolt 263 includes a head portion 267 and a tail portion 268. The head portion 267 is substantially a cross-shaped protrusion configured to extend through the through hole 265, the first latching hole 254 and engage in the shielding frame 30. The tail portion 268 is a plate configured for a user to conveniently rotating the latching bolt 263. The elastic member 269 is a spring sleeved around the latching bolt 263 and positioned between the head portion 267 and the tail portion 268. The elastic member 269 is compressed when the head portion 267 engages in the shielding frame 30 and released when the head portion 267 disengages with the shielding frame 30 to provide elastic force to push out the latching bolt 263 from the corresponding first latching hole 254 and through hole 265.

The shielding frame 30 is metallic and substantially rectangular. The shielding frame 30 includes a bottom wall 31 and a side wall 33 protruding from a peripheral edge of the bottom wall 31. The bottom wall 31 defines a through slot 311 so that the shielding frame 30 forms a frame structure. Two opposite top walls 331 extend from the side wall 33 and are parallel to the bottom wall 31. A plurality of second latching holes 332 are defined in the top walls 331 corresponding to the first latching holes 254 and configured for assembling of the heat dissipating module 25 to the shielding frame 30. A plurality of latching slots 333 are defined in an outer surface of the side wall 31 and configured to engage with the latching blocks 266.

To assemble the shielding assembly to the electronic device, the shielding frame 30 is assembled to the motherboard 10 by fixing the bottom wall 31 on the first surface 11. The CPU 20 is received in the through slot 311 and surrounded by the shielding frame 30. The base 251 is position on the top walls 331 with the first latching holes 254 aligning with the second latching holes 332. The latching plates 262 is positioned on the base 251 with the through holes 265 aligning with the first latching holes 254 and the second latching holes 332. The latching bolts 263 extend through the through holes 265 and the first latching holes 254 and engage in the second latching holes 332 by rotating the latching bolts 263 so that the heat dissipating module 25 is latched to the shielding frame 30 via the fastening assemblies 26. The shielding plate 16 is fixed to the second surface 12 corresponding to the shielding frame 30 to completely shield the CPU 20.

To disassemble the shielding assembly from the electronic device, the tail portions 263 are manually rotated to make the head portions 267 disengage from the second latching holes 332 so that the elastic members 269 push the latching bolts 269 out from the first latching holes 254 and the through holes 265. The heat dissipating module 25 can be detached from the shielding frame 33 without any tools.

In other embodiment, the fastening assemblies 26 may be bolts or rivets which directly extend through the first latching holes 254 and the corresponding second latching holes 332 to fasten the base 251 to the shielding frame 30.

In other embodiments, the latching plate 262 can be directly fixed to the fixing plate 261.

The shielding assembly uses the heat dissipating module 25, the shielding frame 30, and the shielding plate 16 to corporately and completely shield the CPU 20 that space is saved on the motherboard 10 and also effectively shield the CPU 20 from other electronic elements of the motherboard 10.

It is believed that the exemplary embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A shielding assembly, used for shielding electronic element positioned on a motherboard of an electronic device, comprising:
a shielding frame fixed to a first surface of the motherboard;
a heat dissipating module detachably assembled to the shielding frame, the heat dissipating module and the shielding frame forming a shielding space to receive the electronic element when the heat dissipating module is assembled to the shielding frame; and
a shielding plate fixed to a second surface of the motherboard opposite to the shielding frame.

2. The shielding assembly of claim 1, wherein the shielding frame comprises a bottom wall and a side wall protruding from a peripheral edge of the bottom wall, the bottom wall defines a through slot, the bottom wall is fixed on the first surface; the electronic element is received in the through slot and surrounded by the shielding frame.

3. The shielding assembly of claim 2, wherein the shielding frame further comprises two opposite top walls extending from the side wall and parallel to the bottom wall, the heat dissipating module comprises a base, the base is fixed to the top walls and resists against the side wall.

4. The shielding assembly of claim 3, wherein the heat dissipating module further comprises a plurality of a fastening assemblies, each fastening assembly comprises a fixing plate, a latching plate hinged to the fixing plate, and a latching bolt, the fixing plate comprises a latching block protruding from an end of the fixing plate facing the latching plate, the latching plate defines a through hole, the latching plate is fixed to the base by the latching bolt and the through hole, the latching block is latched to the shielding frame.

5. The shielding assembly of claim 4, wherein each latching bolt comprises a head portion and a tail portion, the base defines a plurality of first latching holes, each first latching hole for receiving one of the fastening assemblies, the top walls defines a plurality of second latching holes, each second latching hole aligned with one of the first latching holes, each latching bolt extends through the corresponding through hole, the corresponding first latching hole and engages in the corresponding second latching hole.

6. The shielding assembly of claim 5, wherein the latching bolt further comprises a plurality of elastic members corresponding to the fastening assemblies, each elastic member is sleeved around the corresponding latching bolt and positioned between the head portion and the tail portion, the elastic member is compressed when the head portion engages in the corresponding second latching hole and released when the head portion disengages with the corresponding second latching hole to push out the latching bolt from the corresponding first latching hole and through hole.

7. The shielding assembly of claim 4, wherein the side wall defines a plurality of latching slots corresponding to the latching blocks, each latching block latches to the corresponding latching slot.

8. An electronic device, comprising:
a motherboard comprising a first surface and a second surface opposite to the first surface;
an electronic element positioned on the first surface of the motherboard; and
a shielding assembly, comprising:
a shielding frame secured to the motherboard and surrounding the electronic element;
a heat dissipating module detachably assembled to the shielding frame, the heat dissipating module and the shielding frame forming a shielding space to receive the electronic element when the heat dissipating module is assembled to the shielding frame; and
a shielding plate fixed to the second surface of the motherboard opposite to the shielding frame.

9. The shielding assembly of claim 8, wherein the shielding frame comprises a bottom wall and a side wall protruding from a peripheral edge of the bottom wall, the bottom wall defines a through slot, the bottom wall is fixed on the first surface; the electronic element is received in the through slot and surrounded by the shielding frame.

10. The shielding assembly of claim 9, wherein the shielding frame further comprises two opposite top walls extending from the side wall and parallel to the bottom wall, the heat dissipating module comprises a base, the base is fixed to the top walls and resists against the side wall.

11. The shielding assembly of claim 10, wherein the heat dissipating module further comprises a plurality of a fastening assemblies, each fastening assembly comprises a fixing plate, a latching plate hinged to the fixing plate, and a latching bolt, the fixing plate comprises a latching block protruding from an end of the fixing plate facing the latching plate, the latching plate defines a through hole, the latching plate is fixed to the base by the latching bolt and the through hole, the latching block is latched to the shielding frame.

12. The shielding assembly of claim 11, wherein each latching bolt comprises a head portion and a tail portion, the base defines a plurality of first latching holes corresponding to the fastening assemblies, the top walls defines a plurality of second latching holes corresponding to the first latching holes, each latching bolt extends through the corresponding through hole, the corresponding first latching hole and engages in the corresponding second latching hole.

13. The shielding assembly of claim 12, wherein the latching bolt further comprises a plurality of elastic members corresponding to the fastening assemblies, each elastic member is sleeved around the corresponding latching bolt and positioned between the head portion and the tail portion, the elastic member is compressed when the head portion engages in the corresponding second latching hole and released when the head portion disengages with the corresponding second latching hole to push out the latching bolt from the corresponding first latching hole and through hole.

14. The shielding assembly of claim 11, wherein the side wall defines a plurality of latching slots corresponding to the latching blocks, each latching block latches to the corresponding latching slot.
